(19) United States
(12) Patent Application Publication
(10) Pub. No.: US 2010/0213649 A1
(43) Pub. Date: Aug. 26, 2010

(54) Shock Absorber and Assembling Method of Electronic Device Using the Same

(75) Inventors: Hong Wen Lee, Taipei City (TW); Yi Ming Chang, Taipei City (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: COMPAL ELECTRONICS, INC., Taipei City (TW)

(21) Appl. No.: 12/472,750

(22) Filed: May 27, 2009

(30) Foreign Application Priority Data
Feb. 23, 2009 (TW) 98105654

(51) Int. Cl. F16F 3/04; H05K 13/00

(52) U.S. Cl. 267/93; 29/592.1

(57) ABSTRACT

A shock absorber and an assembling method of an electronic device using the same are provided. The shock absorber includes a first connecting portion, a second connecting portion and a number of elastic arms. The two connecting portions respectively connect to a housing and a circuit board of the electronic device. Two ends of each elastic arm are respectively connected to the two connecting portions to buffer the relative movement between the housing and the circuit board. The method includes the following steps. First, the shock absorber including the first connecting portion, the second connecting portion and the elastic arms is provided. Then the second connecting portion is connected to a surface of the circuit board surrounding a through hole of the circuit board. After connecting the second connecting portion, the housing is connected to the first connecting portion.

### RELATED APPLICATIONS

This application claims priority to Taiwan Application Serial Number 98105654, filed Feb. 23, 2009, which is herein incorporated by reference.

### BACKGROUND

1. Field of Invention

The present invention relates to a shock absorber and an assembling method of an electronic device using the same. More particularly, the present invention relates to a shock absorber protecting the elements of the electronic device from stress damage and an assembling method of the electronic device using the same.

2. Description of Related Art

Generally, consumer electronic devices have a number of delicate components disposed on a main board, and the main board is directly fixed to the case. Take the notebook computer as an example, the memory controller hub (MCH), the I/O controller hub (ICH), the central processing unit (CPU) and other chip sets are disposed on the printed circuit board (PCB), and the PCB is directly fixed onto the case of the notebook computer.

However, the electronic device can be subject to impact or collisions during the assembly, packing and delivering processes, or even when the user is using the electronic device. When the electronic device is subject to collisions or external forces, the case of the electronic device may easily be twisted, or the main board may be shifted relative to the case. Due to the fact that the main board is directly fixed to the case, the stress generated from collisions, impacts and distortions of the case are directly transferred to the main board, resulting in the deformation of the main board. The solder material for soldering the elements on the main board may crack or, in a worse case, fracture. Therefore, the ability of the electronic device to protect its inner elements during an impact is degraded, the yield rate is lowered, and the manufacturing cost is increased accordingly.

### SUMMARY

A shock absorber and an assembling method and an electronic device using the same are provided. The relative movement between a housing and a circuit board of the electronic device is buffered through the elastic arms of the shock absorber. The damage caused by the relative movement between elements can be prevented.

According to one aspect of the invention, a shock absorber that is applicable to an electronic device is provided. The shock absorber includes a first connecting portion, a second connecting portion and a number of elastic arms. The two connecting portions are used for connecting a housing and a circuit board of the electronic device respectively. The elastic arms are disposed between the housing and the circuit board. Two ends of each elastic arm are connected to the first connecting portion and the second connecting portion respectively, to buffer the relative movement between the housing and the circuit board.

According to another aspect of the invention, an assembling method of an electronic device is provided. The method at least includes the following steps. First, a shock absorber including a first connecting portion, a second connecting portion and a number of elastic arms is provided. The elastic arms are disposed between the first connecting portion and the second connecting portion. Two ends of each elastic arm are respectively connected to the first connecting portion and the second connecting portion. Then the second connecting portion is connected to a surface of a circuit board surrounding a through hole of the circuit board. After connecting the second connecting portion, a housing is connected to the first connecting portion.

In the shock absorber and the assembling method of the electronic device using the same of the present invention, the relative movement between the housing and the circuit board of the electronic device is buffered through the elastic arms that are disposed between the two connecting portions. The stress originating from the relative movement between elements can be buffered. Further, the distortion, bending and even fracture of the elements caused by stress damages can be prevented accordingly.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a three-dimensional diagram of the shock absorber according to one embodiment of the invention;

FIG. 2A is a top view of the shock absorber in FIG. 1;

FIG. 2B is a cross-sectional view of the shock absorber in FIG. 2A along line A-A′;

FIG. 3 illustrates the circuit board according to one embodiment of the invention;

FIG. 4 illustrates the housing according to one embodiment of the invention;

FIG. 5 is a cross-sectional view of the shock absorber connected with the circuit board;

FIG. 6 is a cross-sectional view of the shock absorber connected with the circuit board and the housing;

FIG. 7 is a top view of the shock absorber according to another embodiment of the invention; and

FIG. 8 is a top view of the shock absorber according to a further embodiment of the invention.

### DETAILED DESCRIPTION

Reference will now be made in detail to the present embodiments of the invention, examples of which are illustrated in the accompanying drawings.

In the shock absorber and the assembling method of the electronic device using the same according to one embodiment of the invention, several elastic arms that are individually connected to the first connecting portion and the second connecting portion are used to buffer the relative movement between the housing, which is connected to the first connecting portion, and the circuit board, which is connected to the second connecting portion. The stress originated from the relative movement will not apply to the elements, and the problem of element damages can be further avoided.

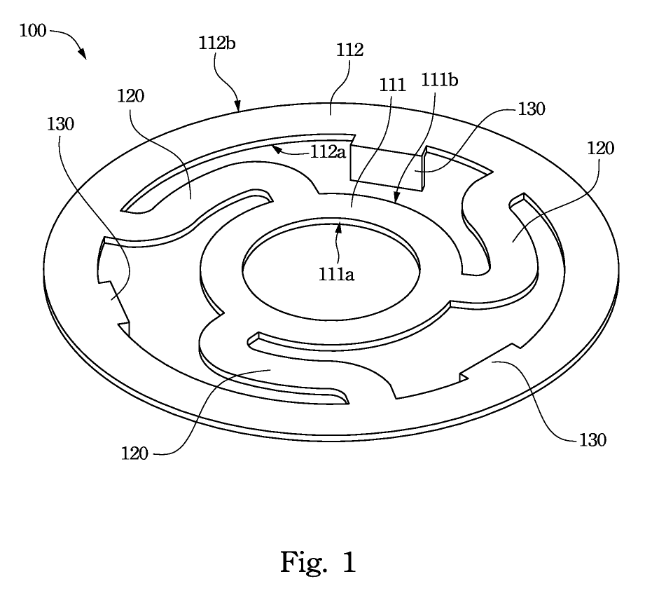

The shock absorber according to one embodiment of the invention is elaborated below. Please refer to FIG. 1. A three-dimensional diagram of the shock absorber according to one embodiment of the invention is illustrated in FIG. 1. The shock absorber 100 includes a first connecting portion 111, a second connecting portion 112 and a number of elastic arms 120. The elastic arms 120 are disposed between the first connecting portion 111 and the second connecting portion 112, and two ends of each elastic arm 120 are respectively connected to the first connecting portion 111 and the second connecting portion 112. The shock absorber 100 is applicable to an electronic device. The first connecting portion 111 and the second connecting portion 112 are respectively connected to a housing and a circuit board of the electronic device. The elastic arms 120 are used to buffer the relative movement between the housing and the circuit board. Therefore damage caused by stress is prevented. The housing and the circuit board of the present embodiment will be further detailed below.

More specifically, the first connecting portion 111 and the second connecting portion 112 of the present embodiment are circular rings. The shock absorber 100 of the present embodiment is generally round-shaped. The first connecting portion 111 is surrounded by the second connecting portion 112. As shown in FIG. 1, the first connecting portion 111 has an inner edge 111a and an outer edge 111b, and the second connecting portion 112 has an inner edge 112a and an outer edge 112b. Two ends of each elastic arm 120 are respectively connected to the outer edge 111b of the first connecting portion 111 and the inner edge 112a of the second connecting portion 112. The elastic arms 120 are equidistantly connected to the outer edge 111b of the first connecting portion 111 through one end of each elastic arm 120. The other ends of the elastic arms 120 are equidistantly connected to the inner edge 112b of the second connecting portion 112. In another example, the two ends of the elastic arms 120 are non-equidistantly connected to the first connecting portion 111 and the second connecting portion 112. In the present embodiment, each elastic arm 120 is exemplarily S-shaped. The place where each elastic arm 120 is connected to the first connecting portion 111 and the place where each elastic arm 120 is connected to the second connecting portion 112 are situated in different radii of the shock absorber 100; that is, the portion of each elastic arm 120 connected to the first connecting portion 111 is displaced with the portion of each elastic arm 120 connected to the second connecting portion 112.

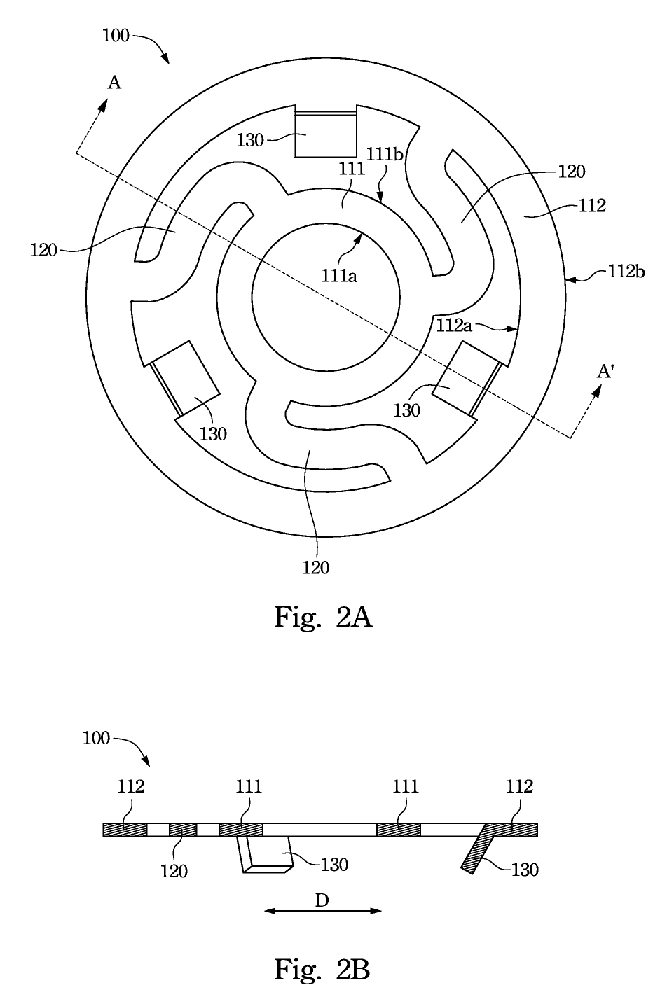

On the other hand, the shock absorber 100 further includes a number of positioning portions 130. Please refer to FIG. 2A and FIG. 2B at the same time. FIG. 2A illustrates the top view of the shock absorber in FIG. 1 and a cross-sectional view of the shock absorber in FIG. 2A along line A-A′ is illustrated in FIG. 2B. The positioning portions 130 are connected to the second connecting portion 112 to position the shock absorber 100 on the circuit board of the electronic device. As shown in FIG. 2B, the positioning portions 130 protrude from a surface of the shock absorber 100 in a non-parallel direction to the radial direction D of the shock absorber 100. In practical use, the first connecting portion 111, the second connecting portion 112 and the elastic arms 120 form a flat plate structure. The first connecting portion 111, the second connecting portion 112, the elastic arms 120 and the positioning portions 130 are preferably formed in one piece.

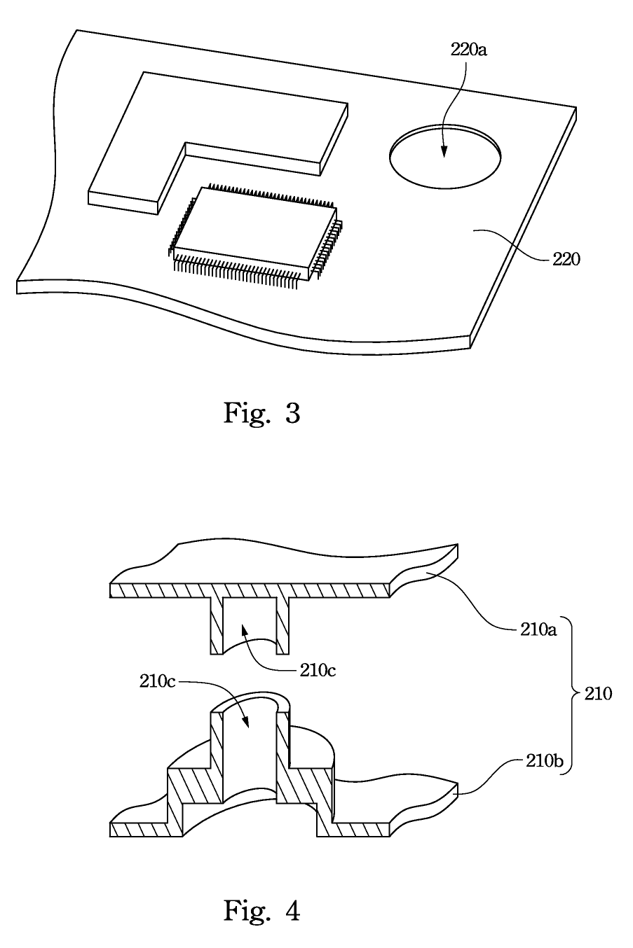

Hereinafter, the assembling method of the electronic device according to one embodiment of the invention is elaborated. In the first step of the assembling method the shock absorber 100 is provided. The shock absorber 100 according to one embodiment of the invention, as shown in FIG. 1, is provided in this step. Please refer to FIG. 3 and FIG. 4 at the same time. The circuit board according to one embodiment of the invention is shown in FIG. 3 and the housing according to one embodiment of the invention is shown in FIG. 4. The housing 210 includes an upper casing 210a and a lower casing 210b and has a fixing hole 210c. The circuit board 220 has a through hole 220a.

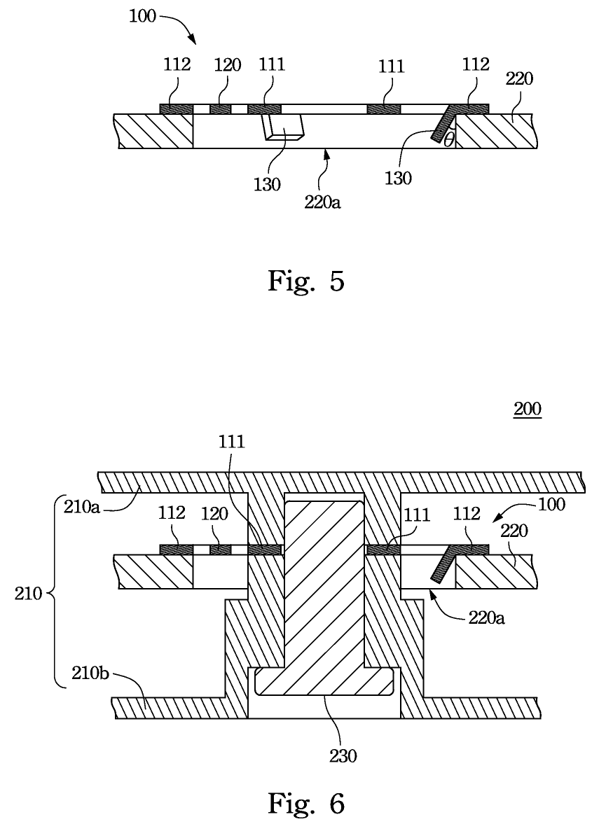

In the next step of the assembling method of the present embodiment, the second connecting portion 112 is connected to the circuit board 220. Refer to FIG. 5. FIG. 5 illustrates a cross-sectional view of the shock absorber connected with the circuit board. The second connecting portion 112 of the shock absorber 100 is connected to a surface of the circuit board 220 surrounding the through hole 220a in this step. Practically, the second connecting portion 112 of the shock absorber 100 is connected to the circuit board 220 through the surface mount technology (SMT). A material having flexibility and the ability to tolerate high temperatures in the tinning furnace, such as copper, can be selected as the shock absorber 100 material. Therefore, the shock absorber 100 can be disposed onto the circuit board 220 simultaneously with surface mounting the components on the circuit board 220. As a result, the manufacturing process is simplified and the manufacturing cost is reduced. In addition to that, in the present embodiment, the diameter of the through hole 220a is larger than the outer diameter of the first connecting portion 111, so the first connecting portion 111 is not in contact with the circuit board 220 when the second connecting portion 112 is connected to the circuit board 220. Thus the first connecting portion 111 is floated at the through hole 220a by the supporting of the elastic arms 120. In this manner, the first connecting portion 111 is movable relative to the second connecting portion 112 in a direction parallel and perpendicular to the radial direction D of the shock absorber 100.

When the second connecting portion 112 is connected to the circuit board 220 described in the above, the positioning portions 130 are in contact with a lateral wall of the through hole 220a. The second connecting portion 112 is connected to the surface of the circuit board 220 surrounding the through hole 220a to position the shock absorber 100 at a place of the circuit board 220 corresponding to the through hole 220a. More specifically, each positioning portion 130 and the lateral wall of the through hole 220a have an acute included angle θ there between, thereby facilitating the positioning of the shock absorber 100.

Afterwards, the assembling method of the present embodiment performs a step of connecting the housing 210 to the first connecting portion 111 after connecting the second connecting portion 112 to the circuit board 220. Refer to FIG. 6. FIG. 6 is a cross-sectional view of the shock absorber connected with the circuit bard and the housing is illustrated. In this step, the housing 210 is connected to the first connecting portion 111 via a fixing element 230. The housing 210 of the present embodiment includes the upper casing 210a and the lower casing 210b. The fixing element 230 is exemplified by a screw. The upper casing 210a and the lower casing 210b are respectively in contact with two opposite surfaces of the first connecting portion 111. The housing 210 is fastened to the first connecting portion 111 by way of screwing the screw into the fixing hole 210c. However, the manner of connecting the housing 210 to the first connecting portion 111 is not merely limited to the screwing fashion. In another example, the housing 210 is adhered or soldered onto the first connecting portion 111.

The assembling method of the electronic device 200 is complete after the first connecting portion 111 and the second connecting portion 112 are connected to the housing 210 and the circuit board 220. The electronic device 200 mainly includes the housing 210, the circuit board 220 and the shock absorber 100. The elastic arms 210 of the shock absorber 100 are used to buffer the relative movement between the housing 210 and the circuit board 220. While packaging and delivering the electronic device 200, or while the user uses the electronic device 200, the movement of the housing 210 relative to the circuit board 220 in the directions parallel to and perpendicular to the radial direction D of the shock absorber 100 is buffered. When the deformation of the housing 210 caused by collisions or external forces of the electronic device 200 occurs, the relative movement of the housing 210 relative to the circuit board 220 is buffered and the deformation of the housing 210 is absorbed by the elastic arms 120. As a result, the stress is not transferred to the circuit board 220, and the problem of element damages can be prevented.

The shock absorber 100 of the present embodiment is exemplified by including three elastic arms 120 and three positioning portions 130, as shown in FIG. 1. However, one who is skilled in the related art can understand that the number of the elastic arms 120 or the positioning portions 130 is not limited thereto and the elastic arms 120 are not limited to S-shape. Any disposition having the first connecting portion 111 connected to the second connecting portion 112 through the elastic arms 120 to buffer the relative movement between the first connecting portion 111 and the second connecting portion 112 is covered within the scope of the present invention.

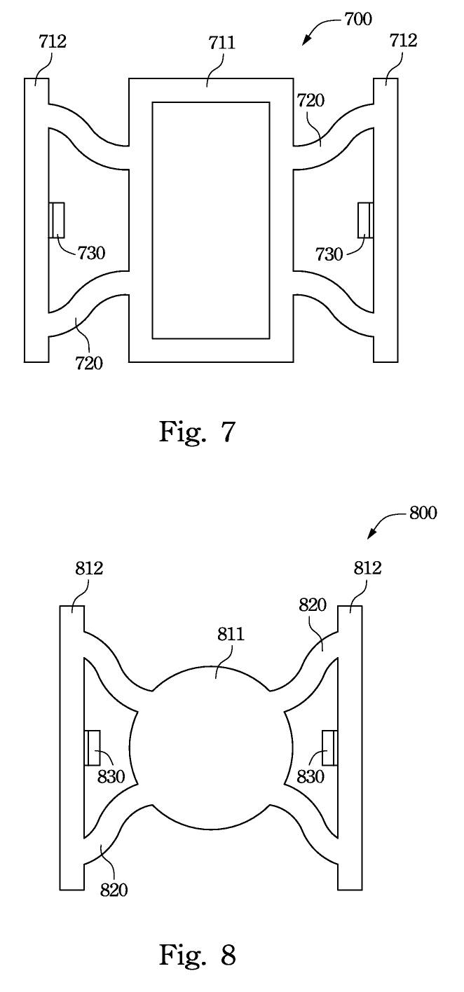

In the foregoing shock absorber 100 of the present embodiment, the first connecting portion 111 and the second connecting portion 112 are exemplified by circular rings as shown in FIG. 2A. However, the shape of the first connecting portion 111 or the second connecting portion 112 is not limited thereto. For example, the first connecting portion 111 can be a polygon. Referring to FIG. 7, a top view of the shock absorber according to another embodiment of the invention is illustrated. The shock absorber 700 includes a first connecting portion 711, a number of elastic arms 720 and a second connecting portion 712. The first connecting portion 711 is a rectangular strip having a rectangular opening in the middle. The second connecting portion 712 includes two stripe segments respectively disposed at two opposite sides of the first connecting portion 711. Besides that, the shock absorber 700 further includes a number of positioning portions 730. The positioning portions 730 are individually connected to the two stripe segments of the second connecting portion 712 disposed at two opposite sides of the first connecting portion 711. The shock absorber 700 includes four elastic arms 720. Two of the elastic arms 720 are disposed between the first connecting portion 711 and one stripe segment of the second connecting portion 712. The other two elastic arms 720 are disposed between the first connecting portion 711 and the other stripe segment of the second connecting portion 712.

Further, the first connecting portion 111 or 711 of the present embodiment is exemplified by a close-loop structure, yet the first connecting portion 111 or 711 can also be a flat plate. Please refer to FIG. 8. A top view of the shock absorber according to a further embodiment of the invention is illustrated. The shock absorber 800 includes a first connecting portion 811, a number of elastic arms 820, a second connecting portion 812 and a number of positioning portions 830. The first connecting portion 811 is a flat plate. The housing of the electronic device is adhered or soldered onto the first connecting portion 811.

In the above-described shock absorber and the assembling method of the electronic device using the same according to the embodiments of the invention, the relative movement between the housing, connected to the first connecting portion, and the circuit board, connected to the second connecting portion, and the deformation of the housing caused by external forces, can be buffered through several elastic arms connected to the two connecting portions. Therefore, the stress originating from the relative movement and the deformation does not apply to the circuit board, and the problem of damaging the circuit board is prevented. Further, because the second connecting portion is connected to the circuit board through the surface mount technology, the manufacturing process is simplified, the assembling convenience is increased, and the cost is reduced accordingly.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A shock absorber applicable to an electronic device, comprising:
a first connecting portion and a second connecting portion for respectively connecting to a housing and a circuit board of the electronic device; and
a plurality of elastic arms disposed between the first connecting portion and the second connecting portion, wherein two ends of each elastic arm are respectively connected to the first connecting portion and the second connecting portion for buffering the relative movement between the housing and the circuit board.

2. The shock absorber of claim 1, wherein the first connecting portion is surrounded by the second connecting portion.

3. The shock absorber of claim 2, wherein the first connecting portion and the second connecting portion are circular rings.

4. The shock absorber of claim 3, wherein the circuit board has a through hole, and the second connecting portion is connected to a surface of the circuit board surrounding the through hole.

5. The shock absorber of claim 4, wherein the diameter of the through hole is larger than the outer diameter of the first connecting portion.

6. The shock absorber of claim 4 further comprising:
a plurality of positioning portions connected to the second connecting portion for positioning the shock absorber on the circuit board, wherein the positioning portions are protruded from a surface of the shock absorber in a direction nonparallel to the radial direction of the shock absorber.

7. The shock absorber of claim 6, wherein when the second connecting portion is connected to the surface of the circuit board surrounding the through hole, the positioning portions is in contact with a lateral wall of the through hole to position the shock absorber at a place of the circuit board corresponding to the through hole.

8. The shock absorber of claim 3, wherein the place where each elastic arm is connected to the first connecting portion and the place where each elastic arm is connected to the second connecting portion are situated in different radii.

9. The shock absorber of claim 1, wherein each elastic arm is S-shaped.

10. The shock absorber of claim 1, wherein the first connecting portion and the second connecting portion individually have an inner edge and an outer edge, and two ends of each elastic arm are respectively connected to the outer edge of the first connecting portion and the inner edge of the second connecting portion.

11. The shock absorber of claim 1, wherein the shock absorber is connected to the circuit board through the surface mount technology (SMT).

12. The shock absorber of claim 1, wherein the first connecting portion, the second connecting portion and the elastic arms are formed in one piece.

13. The shock absorber of claim 1, wherein the first connecting portion, the second connecting portion and the elastic arms form a flat plate structure.

14. An assembling method of an electronic device, comprising:
providing a shock absorber comprising a first connecting portion, a second connecting portion and a plurality of elastic arms, wherein the elastic arms are disposed between the first connecting portion and the second connecting portion, and two ends of each elastic arm are respectively connected to the first connecting portion and the second connecting portion;
connecting the second connecting portion to a surface of a circuit board surrounding a through hole of the circuit board; and
connecting a housing to the first connecting portion after connecting the second connecting portion to the circuit board.

15. The assembling method of claim 14, wherein in the step of providing the shock absorber, the first connecting portion is surrounded by the second connecting portion.

16. The assembling method of claim 14, wherein in the step of connecting the second connecting portion, the second connecting portion is connected to the surface of the circuit board surrounding the through hole through the surface mount technology.

17. The assembling method of claim 14, wherein in the step of providing the shock absorber, the shock absorber further comprises a plurality of positioning portions that are connected to the second connecting portion and are protruded from a surface of the shock absorber in a direction nonparallel to the radial direction of the shock absorber, and the step of connecting the second connecting portion comprises:
positioning the shock absorber at a place of the circuit board corresponding to the through hole via the positioning portions.

18. The assembling method of claim 14, wherein in the step of connecting the housing to the first connecting portion, the housing is connected to the first connecting portion via a fixing element.

19. The assembling method of claim 18, wherein the step of connecting the housing to the first connecting portion comprises:
respectively fastening an upper casing and a lower casing of the housing to two opposite surfaces of the first connecting portion via the fixing element.
